(19) United States
(12) Patent Application Publication
(10) Pub. No.: US 2026/0231345 A1
(43) Pub. Date: Aug. 6, 2026

(54) HDMI FOUR WAY INTERCONNECT-BASED AND INTEGRATED CONTROL BOARD

(71) Applicant: Hyoung Soo KIM, Seoul (KR)

(72) Inventor: Hyoung Soo KIM, Seoul (KR)

(21) Appl. No.: 19/402,880

(22) Filed: Nov. 26, 2025

(30) Foreign Application Priority Data
Jan. 31, 2025 (KR) 10-2025-0012774

(51) Int. Cl. H05K 5/02; G09F 9/33

(52) U.S. Cl. CPC H05K 5/0247; G09F 9/33

(57) ABSTRACT

Disclosed is a high-definition multimedia interface (HDMI) four way interconnected-based and integrated control board, which relates to an integrated control board included in a light-emitting diode (LED) display module consisting of an LED display and a housing, comprising: a module connection part; a control signal input part; a control signal output part; a vertical signal input part; a vertical signal output part; a horizontal signal input part; a horizontal signal output part; and a power source input part.

### CROSS-REFERENCE TO RELATED APPLICATION

This application claims priority to Korean Patent Application No. 10-2025-0012774, filed on Jan. 31, 2024, in the Korean Intellectual Property Office, the entire contents of which are hereby incorporated by reference.

### BACKGROUND OF THE INVENTION

### Field of the Invention

The present invention relates to a high-definition multimedia interface (HDMI) four way interconnect-based and integrated control board, and more specifically, to an HDMI four way interconnect-based and integrated control board which causes a light-emitting diode (LED) display module to be installed by being added and extend freely in vertical and horizontal directions.

### Description of the Related Arts

An electric bulletin board may be used in a stadium and a performance place of a large size, and so on, or in the light of the use of a small scale, the electric bulletin board has been used widely for the exposure of a business enterprise by a general store, a restaurant, a company, or the like.

Recently, as a light-emitting diode (LED) technology become popularized, electric bulletin boards in which an LED device is utilized have mainly been utilized, and thanks to the development of LED devices of a micro size, various screens can be embodied, so the electric bulletin board has been used widely. Since it is advantageous in that the LED technology is stable and trustworthy, the consumption of electricity is small and the LED technology is long-lived, there has been an increase in demand.

With respect to an LED-based electric bulletin board module, a large number of LED-based electric bulletin board panels form one electric bulletin board by being combined with one another in plural number, and it has been required to develop technology capable of additionally extending and installing an LED display module according to an installation environment and as needed by developing the LED-based electric bulletin board according to such a conventional art more and more.

### Prior Art Document

### Patent Document

Patent Document: Granted-Patent Announcement No. 10-1198516 (November 6, 2012)

### SUMMARY OF THE INVENTION

The present invention has been devised for solving the aforesaid problems, and the present invention is intended for providing a high-definition multimedia interface (HDMI) four way interconnect-based light-emitting diode (LED) display module and which cause the LED display module to be installed by being added and extend freely in vertical and horizontal directions.

An HDMI four way interconnect-based and integrated control board according to one exemplary embodiment of the present invention intended for solving the aforesaid problems relates to an integrated control board 110 included in a light-emitting diode (LED) display module 100 consisting of an LED display 101 and a housing, and the integrated control board may comprise: a module connection part 111 configured to fix the integrated control board 110 to the housing; a control signal input part 112 configured to input and receive a control signal intended for an indication of the LED display 101; a control signal output part 113 configured to output the control signal intended for the indication of the LED display 101; a vertical signal input part 114 configured to receive a vertical signal by being connected to an integrated control board of another LED display module located in a vertical direction; a vertical signal output part 115 configured to output the vertical signal by being connected to the integrated control board of said another LED display module located in the vertical direction; a horizontal signal input part 116 configured to receive a horizontal signal by being connected to an integrated control board of another LED display module located in a horizontal direction; a horizontal signal output part 117 configured to output the horizontal signal by being connected to the integrated control board of said another LED display module located in the horizontal direction; and a power source input part 118 configured to input and receive a power source.

In accordance with another exemplary embodiment of the present invention, the HDMI four way interconnect-based and integrated control board may further comprise a power source sensing interface 119 configured to sense the power source inputted through the power source input part 118.

In accordance with another exemplary embodiment of the present invention, the HDMI four way interconnect-based and integrated control board may further comprise: a vertical signal input indication part 120 configured to indicate an inputted state of the vertical signal; a horizontal signal input indication part 121 configured to indicate an inputted state of the horizontal signal.

In accordance with another exemplary embodiment of the present invention, the HDMI four way interconnect-based and integrated control board may further comprise: a test button 122 configured to provide displaying and setting of a test screen of the LED display 101; and a liquid crystal display (LCD) connector 123 configured to provide the connection of an external LCD module.

In accordance with the other exemplary embodiment of the present invention, the HDMI four way interconnect-based and integrated control board may further comprise: a power source part 103 received in an inner portion of the LED display 101 and the housing 102, thereby supplying a power source to the LED display 101 and the HDMI four way interconnect-based and integrated control board.

According to the present invention, thanks to the development of an LED-based electric bulletin board according to the conventional art, the HDMI four way interconnect-based LED display module and the HDMI four way interconnect-based and integrated control board, which cause the LED display module to be installed by being added and extend freely in the vertical and horizontal directions as needed, can be provided.

### BRIEF DESCRIPTION OF THE DRAWINGS

FIG. 1 is a view illustrating a high-definition multimedia interface (HDMI) four way interconnect-based light-emitting diode (LED) display module according to one exemplary embodiment of the present invention.

FIG. 2 is a perspective view showing disassembly of the HDMI four way interconnect-based LED display module according to another exemplary embodiment of the present invention.

FIG. 3 is a view illustrating an LED display according to another exemplary embodiment of the present invention.

FIG. 4 is a view illustrating a housing according to another exemplary embodiment of the present invention.

FIGS. 5A and 5B are views illustrating an HDMI four way interconnect-based and integrated control board according to another exemplary embodiment of the present invention.

FIG. 6 is a view intended for describing a control signal band and a control signal cable according to another exemplary embodiment of the present invention.

FIG. 7 is a view intended for describing a connection method of the HDMI four way interconnect-based and integrated control board according to another exemplary embodiment of the present invention.

FIG. 8 is a flow chart intended for describing an installation method of the HDMI four way interconnect-based LED display module according to the other exemplary embodiment of the present invention.

### DETAILED DESCRIPTION OF THE INVENTION

The present invention can be convertible variously and can have various exemplary embodiments, and the specific exemplary embodiments are illustrated in the drawings and are described in detail in the detailed description of the present invention. However, they shouldn't be regarded as limiting the present invention to specially embodied forms, but should be understood as including all the modifications, equivalents, or alternations included in the idea and the technical scope of the present invention.

However, in the following description with regard to embodied forms, it is to be noted that, when the detailed description of conventional functions or constitutions related with the present invention may make the gist of the present invention unnecessarily unclear, the detailed description thereof will be omitted. Also, it should be understood that the sizes of the constituent elements shown in the drawings may be drawn exaggeratedly for the description, and do not mean actually applied sizes.

Also, throughout the present specification, when it is described that one constituent element “is connected” or “linked” to another constituent element, although said one constituent element may directly be connected or may directly be linked to said another constituent element, it should be understood that these constituent elements may be connected or linked to each other via the other constituent element therebetween, unless the context clearly indicates otherwise. Also, throughout the present specification, when it is described that a part “comprises” a constituent element, this means that the part may further comprise the other constituent elements rather than excluding the other constituent elements, unless the context clearly indicates otherwise.

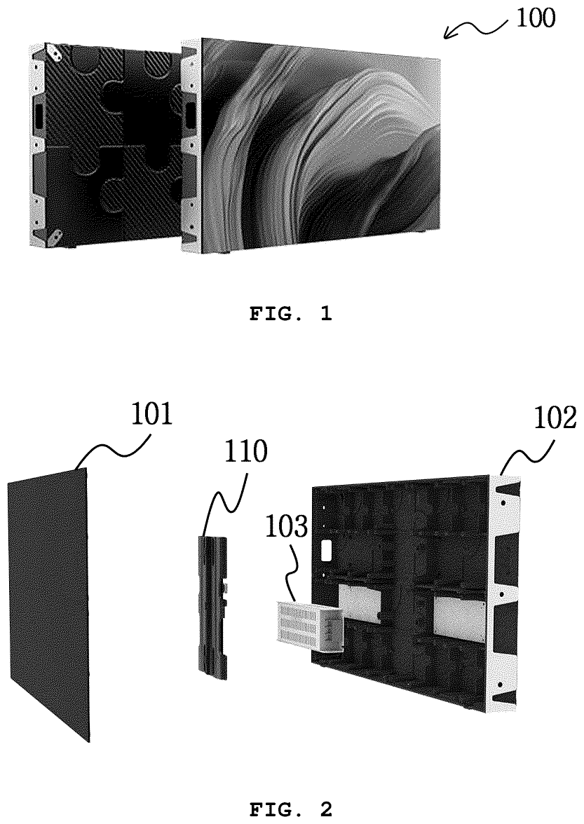

FIG. 1 is a view illustrating a high-definition multimedia interface (HDMI) four way interconnect-based light-emitting diode (LED) display module according to one exemplary embodiment of the present invention and FIG. 2 is a perspective view showing disassembly of the HDMI four way interconnect-based LED display module according to another exemplary embodiment of the present invention.

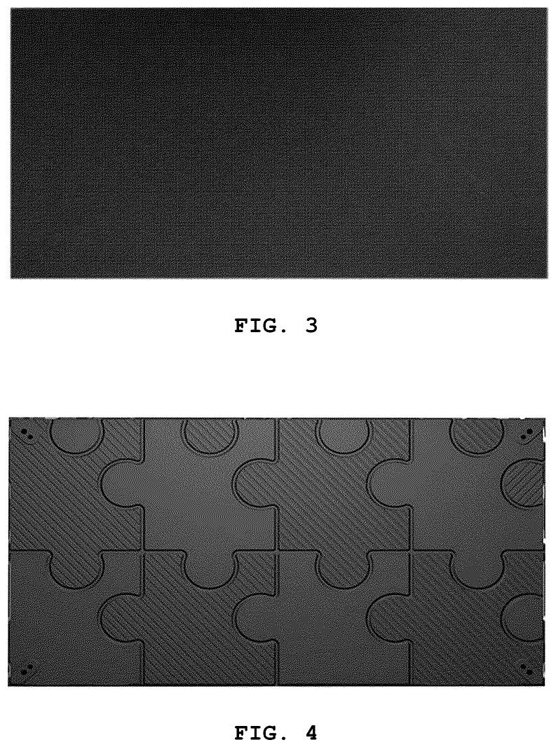

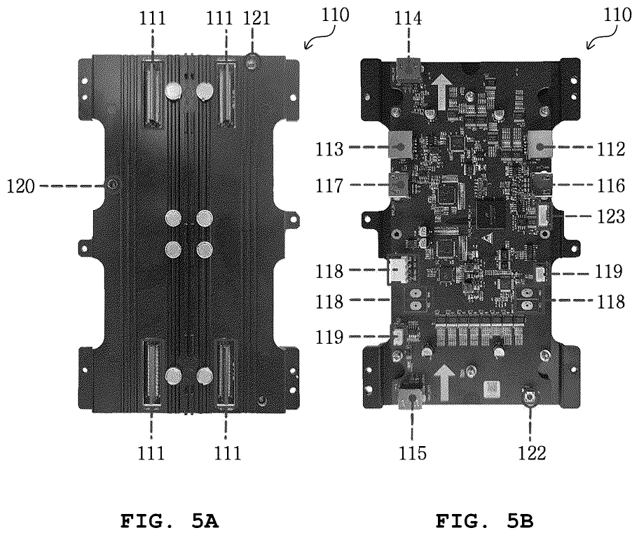

Also, FIG. 3 is a view illustrating an LED display according to said another exemplary embodiment of the present invention and FIG. 4 is a view illustrating a housing according to another exemplary embodiment of the present invention. FIGS. 5A and 5B are views illustrating an HDMI four way interconnect-based and integrated control board according to another exemplary embodiment of the present invention.

With reference to FIG. 1 to FIG. 5B, the HDMI four way interconnect-based LED display module and the HDMI four way interconnect-based and integrated control board are described.

The HDMI four way interconnect-based LED display module according to said one exemplary embodiment comprises: the LED display 101; the housing 102; a power source part 103; and the 110.

The LED display 101 is configured to comprise a plurality of LED modules and the LED display 101 is combined with the housing 102.

Also, the power source part 103 and the HDMI four way interconnect-based and integrated control board 110 are combined with the housing 102 and are received into an internal space between the LED display 101 and the housing 102, and the power source part 103 supplies electric power to the LED display 101 and 110.

Referring to FIGS. 5A and 5B, the HDMI four way interconnect-based and integrated control board 110 may comprise: a module connection part 111; a control signal input part 112; a control signal output part 113; a vertical signal input part 114; a vertical signal output part 115; a horizontal signal input part 116; a horizontal signal output part 117; a power source input part 118; a power source sensing interface 119; a vertical signal input indication part 120; a horizontal signal input indication part 121; a test button 122; and a liquid crystal display (LCD) connector 123.

The module connection part 111 fixes the integrated control board 110 to the housing.

The control signal input part 112 inputs and receives a control signal intended for an indication of the LED display 101, and the control signal output part 113 outputs the control signal intended for the indication of the LED display 101. At this time, the control signal input part 112 and the control signal output part 113, which are connectors with which RJ45 is able to be connected, may provide the transmission of 485 signals intended for forming LED display data and the transmission of a super 2K having load and a next 2K direct cascade.

Also, the vertical signal input part 114 receives a vertical signal by being connected to an integrated control board of another LED display module located in a vertical direction, and the vertical signal output part 115 outputs a vertical signal by being connected to the integrated control board of said another LED display module located in the vertical direction. The vertical signal input part 114 and the vertical signal output part 115 configured as described above may be formed to support HDMI 1.3 and 2K @ 60 Hz into the shape of a connector.

The horizontal signal input part 116 receives a horizontal signal by being connected to an integrated control board of another LED display module located in a horizontal direction, and the horizontal signal output part 117 outputs the horizontal signal by being connected to the integrated control board of said another LED display module located in the horizontal direction.

The power source input part 118 inputs and receives a power source through the power source part 103, and the power source sensing interface 119 senses the power source inputted through the power source input part 118.

Also, the vertical signal input indication part 120 indicates an inputted state of the vertical signal, and the horizontal signal input indication part 121 indicates an inputted state of the horizontal signal. For example, when the vertical signal input indication part 120 and the horizontal signal input indication part 121 flicker in green, this may express a completed state, and when the vertical signal input indication part and the horizontal signal input indication part are always burning in green, this may express a stand-by state.

Also, the test button 122 may provide displaying and setting of a test screen of the LED display 101, when the test button 122 is pressed after the separation of an HDMI cable, the test screen is displayed in the display, when the test button is pressed continuously, the test screen is able to change, and the LCD connector 123 may provide a screen for a test and information by providing the connection of an external LCD module.

Based on such a constitution, the HDMI four way interconnect-based LED display module and the HDMI four way interconnect-based and integrated control board according to the present invention may provide a standard 16:9 display for a point-to-point connection beyond 2K, 4K, and 8K and may also provide a radio transmission design through the integrated control board in an independent intelligence form.

Also, they may be configured to provide two channel HDMI input, to support a 2K @ 60 Hz signal within a range of resolution defined by a user, to provide automatic search for a location and the designation of a location, not to have a necessity for setting up an array diagram, to provide two channel HDMI output, and to support a 2K @ 60 Hz signal cascade.

Also, the HDMI four way interconnect-based LED display module and the HDMI four way interconnect-based and integrated control board may be configured to optimize a fine grayscale function, a grayscale amendment according to each stage, a grayscale jump, a color deviation, pocket marking, and so forth, to develop 18/22 bits and grayscale display effects, to adjust a chroma space, a standard color area of a display, or a color area defined by a user as needed, and to provide an amendment to brightness and chroma and the management of a light board flash in order to ensure consistency of the display.

Also, a function of red, green, blue (RGB) independence gamma adjustment and a function to monitor self-temperatures and voltage may be provided, and sensing of a communication state in real time and displaying of a three-dimensional effect may be provided.

FIG. 6 is a view intended for describing a control signal band and a control signal cable according to another one exemplary embodiment of the present invention.

Within one HDMI band width, only one control signal cable is required. A control line which reaches a main body of a screen from a computer should carry out transmission from 485 to a universal serial bus (USB), as shown in FIG. 6, a first connector of the network cable is connected to signal A of a 485 interface (i.e., an orange-colored line and a white-colored line being connected to signal A of the 485 interface), a second connector of the network cable is connected to signal B of the 485 interface (i.e., an orange-colored line being connected to signal B), and with respect to a cascade connection between 230 W points in the inside of a screen body, transmission from the 485 to the USB isn't required. With respect to the cascade connection between the 230 W points of the inside of the screen, there is no need to use the USB interface at the 485 for conversion, and T568B should be used into the network cable.

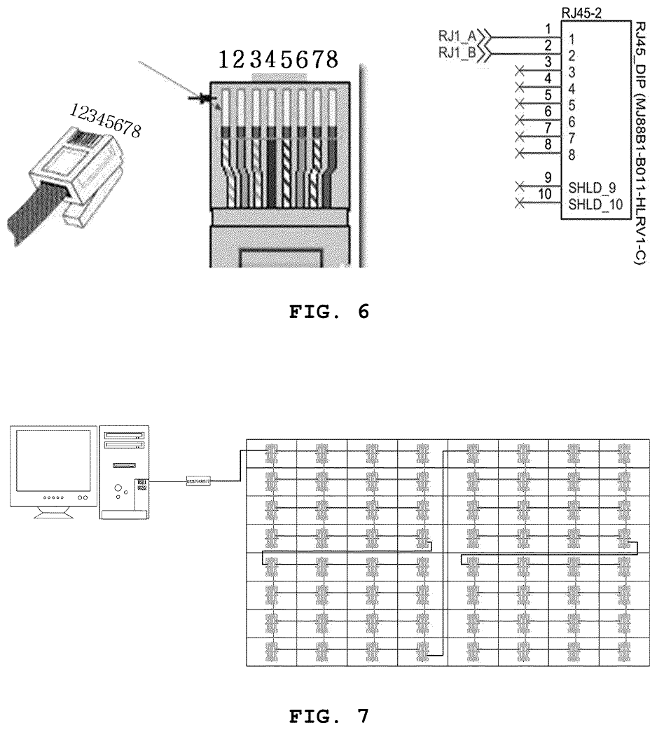

FIG. 7 is a view intended for describing a connection method of the HDMI four way interconnect-based and integrated control board according to another exemplary embodiment of the present invention.

In the case that there are two or more of HDMIs in a screen, in order to realize a series connection as shown in FIG. 7, a blue-colored network cable may be connected.

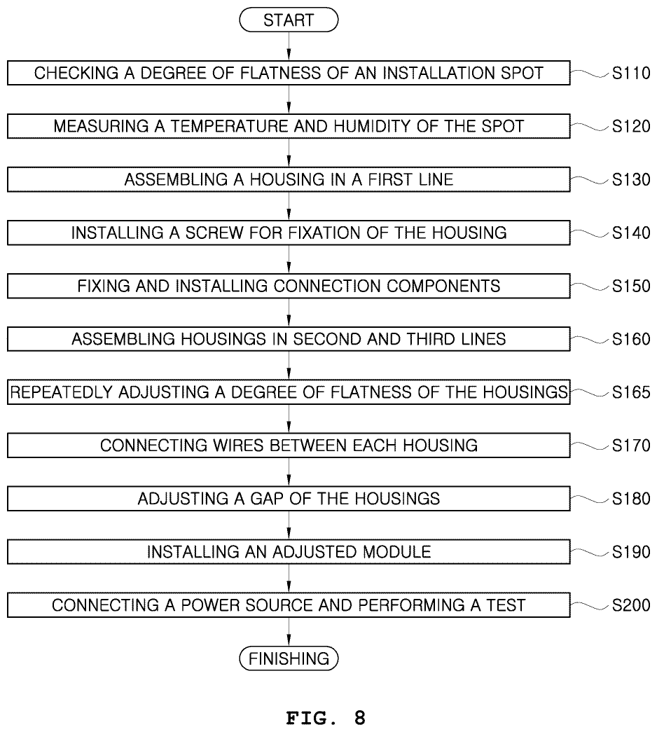

FIG. 8 is a flow chart intended for describing a method of installing the HDMI four way interconnect-based LED display module according to the other exemplary embodiment of the present invention.

Hereinafter, the installation method of the HDMI four way interconnect-based LED display module according to the other exemplary embodiment of the present invention is described with reference to FIG. 8.

First, a degree of flatness of an installation spot is checked S110, and a temperature and humidity of the spot are measured S120.

After this, a housing in a first line is assembled S130, a screw used for fixation of the housing is installed S140, connection components are fixed and installed S150, and housings in second and third lines are assembled S160. When this assembly is carried out, a degree of flatness of the housings may adjusted repeatedly S165.

Then, wires between each housing are connected to one another S170, and a gap of the housings is adjusted S180, and the adjusted module is installed S190.

Like this, when installation is completed, the connection of a power source and a test are performed S200.

As previously described, in the detailed description of the invention, have been described the specific exemplary embodiments of the invention. However, it is to be understood that various modifications can be made without deviating from the idea and the scope of the present invention. The technical idea of the present invention should not be construed as being limited to the aforesaid exemplary embodiments according to the present invention, but should be fixed by the claims and equivalents thereof.

What is claimed is:

1. A high-definition multimedia interface (HDMI) four way interconnected-based and integrated control board, which relates to an integrated control board included in a light-emitting diode (LED) display module consisting of an LED display and a housing, comprising:
a module connection part configured to fix the integrated control board to the housing;
a control signal input part configured to input and receive a control signal intended for an indication of the LED display;
a control signal output part configured to output the control signal intended for the indication of the LED display;
a vertical signal input part configured to receive a vertical signal by being connected to an integrated control board of another LED display module located in a vertical direction;
a vertical signal output part configured to output the vertical signal by being connected to the integrated control board of said another LED display module located in the vertical direction;
a horizontal signal input part configured to receive a horizontal signal by being connected to an integrated control board of another LED display module located in a horizontal direction;
a horizontal signal output part configured to output the horizontal signal by being connected to the integrated control board of said another LED display module located in the horizontal direction; and
a power source input part configured to input and receive a power source.

2. The HDMI four way interconnected-based and integrated control board of claim 1, further comprising a power source sensing interface configured to sense the power source inputted through the power source input part.

3. The HDMI four way interconnected-based and integrated control board of claim 1, further comprising:
a vertical signal input indication part configured to indicate an inputted state of the vertical signal; and
a horizontal signal input indication part configured to indicate an inputted state of the horizontal signal.

4. The HDMI four way interconnected-based and integrated control board of claim 1, further comprising:
a test button configured to provide displaying and setting of a test screen of the LED display; and
a liquid crystal display (LCD) connector configured to provide connection of an external LCD module.

5. The HDMI four way interconnected-based and integrated control board of claim 1, further comprising a power source part received in an inner portion of the LED display and the housing, thereby supplying a power source to the LED display and the HDMI four way interconnect-based and integrated control board.
